(19) United States
(12) Patent Application Publication
(10) Pub. No.: US 2020/0348199 A1
(43) Pub. Date: Nov. 5, 2020

(54) ELECTRONIC DEVICE FOR PRESSURE SENSORS

(71) Applicant: Flexenable Limited, Cambridge (GB)

(72) Inventors: James Harding, Cambridge (GB); Stephen Markham, Cambridge (GB)

(21) Appl. No.: 16/758,983

(22) PCT Filed: Oct. 22, 2018
(86) PCT No.: PCT/EP2018/078909

§ 371 Date: Apr. 24, 2020

(30) Foreign Application Priority Data
Oct. 27, 2017 (GB) 1717715.5

(51) Int. Cl. G01L 9/04; H01L 27/12

(52) U.S. Cl. CPC G01L 9/04; H01L 27/124

(57) ABSTRACT

A device comprising: a stack of layers defining an array of transistors, wherein the stack of layers includes a surface conductor pattern defining (i) an array of gate conductors each providing the gate electrodes for a respective column of transistors, and (ii) an array of pixel conductors, each pixel conductor associated with a respective transistor, and connected via a semiconductor channel of the respective transistor to one of an array of row conductors, each row conductor associated with a respective row of transistors; wherein each gate conductor is configured to extend substantially completely around the pixel conductors of the respective column of transistors associated with the gate conductor.

Some pressure sensors make use of the pressure-dependence of the conductivity of a resistor material.

Sensor arrays for e.g. mapping variations in pressure over an area may comprise an active matrix backplane including an array of transistors, each transistor associated with a unique combination of gate and read lines, wherein a surface conductor pattern in electrical contact with a film of pressure-sensitive resistor material defines an array of gate conductors and also a pixel conductor for each transistor. Each pixel conductor for each transistor is connected within a stack of layers to one of an array of read lines via the semiconductor channel for that transistor.

Patterning the film of pressure-sensitive resistor material into islands or cells is one technique for improving the output of such a pressure sensor array, but the inventors for the present application have identified the challenge of improving the output without patterning the pressure-sensitive resistor material.

There is hereby provided a device comprising: a stack of layers defining an array of transistors, wherein the stack of layers includes a surface conductor pattern defining (i) an array of gate conductors each providing the gate electrodes for a respective column of transistors, and (ii) an array of pixel conductors, each pixel conductor associated with a respective transistor, and connected via a semiconductor channel of the respective transistor to one of an array of row conductors, each row conductor associated with a respective row of transistors; wherein each gate conductor is configured to extend substantially completely around the pixel conductors of the respective column of transistors associated with the gate conductor.

According to one embodiment, each gate conductor extends substantially completely around each individual pixel conductor of all the pixel conductors of the respective column of transistors associated with the gate conductor.

There is also hereby provided a pressure sensor, comprising a device as described above and a film of pressure-sensitive resistor material in electrical contact with the surface conductor pattern, wherein the pressure-sensitive material exhibits a pressure-dependent conductivity.

An embodiment of the present invention is described hereunder, by way of example only, with reference to the accompanying drawings, in which:

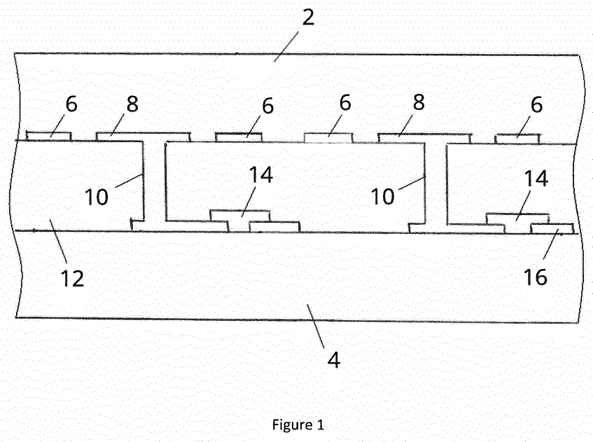

FIG. 1 is a cross-sectional illustration of the configuration of elements of part of a pressure sensor device according to an example embodiment of the present invention; and

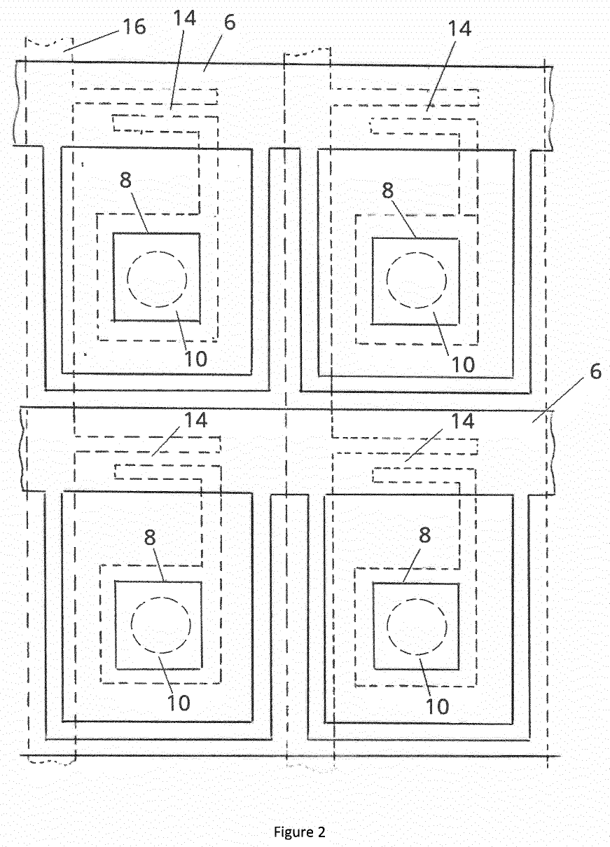

FIG. 2 is a plan illustration of the configuration of an example of surface and lower level conductor patterns for a backplane for a pressure sensor device according to an example embodiment.

A pressure sensor device according to an embodiment of the present invention comprises a film of pressure-sensitive resistor material 2, such as e.g. a resistive elastomer (such as a carbon-doped rubber, whose material density and electrical conductivity changes with a change in the pressure applied), in electrical contact with a surface conductor pattern of a backplane comprising a stack of layers supported on e.g. a plastic support film 4 and defining an active-matrix array of transistors.

In this example embodiment, the active-matrix array of transistors comprises an array of organic transistor devices (such as an array of organic thin film transistor (OTFT) devices) for the control component. OTFTs comprise an organic semiconductor (such as e.g. an organic polymer or small-molecule semiconductor) for the semiconductor channels.

The surface conductor pattern comprises an array of gate lines 6, each gate line providing the gate electrodes for a respective column of transistors of the array of transistors. The surface conductor pattern also comprises an array of pixel conductors 8, each associated with a respective transistor of the transistor array. The pixel conductors 8 are separated from each other and from the gate conductors 6 in the surface conductor pattern.

Each pixel conductor 8 is connected, via a through-hole 10 (shown by dotted lines in FIG. 2) in an insulator 12 and via a semiconductor channel 14 of the respective transistor, to one of an array of read lines 16 defined by another conductor pattern (shown by dotted lines in FIG. 2) at a lower level of the stack. Each read line 16 within the array of read lines is associated with a respective row of transistors, whereby each transistor (and each pixel conductor 8) is associated with a unique combination of gate and read lines.

For the purposes of this patent application, the terms row and column do not indicate any particular absolute directions, but indicate any pair of directions that are substantially orthogonal relative to each other.

Each gate line 6 extends to an edge of the transistor array for connection to a respective terminal of a gate driver chip, and each read line 16 extends to an edge of the transistor array for connection to a respective terminal of a read line driver chip. The gate driver chip and read line driver chip may be separate chips or may be combined into a single chip.

Each gate line 6 is configured to extend around all of the pixel conductors 8 of the transistors associated with the gate line 6. In the example illustrated in FIG. 2, each gate line 6 is further configured to extend individually around each pixel conductor 8 within the set of pixel conductors 8 for the column of transistors associated with the gate line 6.

In operation, the gate driver chip applies “on” voltages to the gate lines 6 in sequence, and the read line chip processes the electrical responses at the read lines 16 as “on” voltages are applied to the gate lines 6 in sequence.

In more detail, the gate driver chip is configured to output an “on” voltage (e.g. a relatively large negative voltage (e.g. −15V) for the example of a p-type semiconductor) to each of its terminals in sequence according to a predetermined timing pattern, while outputting an “off” voltage (e.g. 0V) at the remainder of the output terminals, i.e. all output terminals other than the one terminal that is “on” at any moment in time.

The unpatterned film of pressure-sensitive resistor material 2 unavoidably provides a non-negligible current path between gate lines 6, whereby the application of an “on” voltage to one gate line 6 unavoidably causes a change in the electric potential of adjacent gate lines 6. This cross-talk between gate lines 6 may lead to adjacent columns of transistors (i.e. columns of transistors associated with adjacent gate lines) turning at least partially on at the same time (i.e. more than one column of transistors turning on at the same time).

However, the above-described configuration of the gate lines 6 is designed to minimise the impact on the read line currents of adjacent columns of pixel conductors/transistors that may happen to also be unintentionally “on” by the above-mentioned effect. The extension of each gate line 6 completely around the respective column of pixel conductors 8 (pixel conductors 8 of the column of transistors associated with the gate line 6) has the effect that the potential difference between the intentionally “on” gate line 6 (i.e. the gate line 6 connected to the gate drive chip terminal that is “on”) and all parts of the pixel conductors 8 associated with an adjacent gate line 6 is substantially less than the potential difference between the intentionally “on” gate line 6 and the adjacent gate line 6. Accordingly, the impact of pixel conductors 8 associated with any adjacent gate lines on the currents in the read lines 16 is reduced.

Furthermore, extending each gate line 6 around each individual pixel conductor 8 of the transistors associated with the gate line 6 has the additional effect of minimising the impact of a change in the resistance of the pressure-sensitive resistor film 2 in the region of one pixel conductor 8 in one row on the read line current for adjacent rows.

In one example embodiment, the support substrate may comprise a plastic film, the semiconductor channels 14 may comprise an organic semiconductor such as an organic polymer semiconductor, the insulator 12 may comprise one or more organic polymer materials, and each of the conductor surface and lower level patterns may be formed from a metal/alloy layer or a stack of metal/alloy layers. The stack of layers may comprise additional layers, such as, for example, a layer of organic material to facilitate the transfer of charge carriers between a conductor pattern and the organic semiconductor.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A device comprising: a stack of layers defining an array of transistors, wherein the stack of layers includes a surface conductor pattern defining (i) an array of gate conductors each providing the gate electrodes for a respective column of transistors, and (ii) an array of pixel conductors, each pixel conductor associated with a respective transistor, and connected via a semiconductor channel of the respective transistor to one of an array of row conductors, each row conductor associated with a respective row of transistors; wherein each gate conductor is configured to extend substantially completely around the pixel conductors of the respective column of transistors associated with the gate conductor.

2. The device according to claim 1, wherein each gate conductor extends substantially completely around each individual pixel conductor of all the pixel conductors of the respective column of transistors associated with the gate conductor.

3. A pressure sensor, comprising the device according to claim, and a film of pressure-sensitive resistor material in electrical contact with the surface conductor pattern, wherein the pressure-sensitive material exhibits a pressure-dependent conductivity.

4. A pressure sensor, comprising the device according to claim 2, and a film of pressure-sensitive resistor material in electrical contact with the surface conductor pattern, wherein the pressure-sensitive material exhibits a pressure-dependent conductivity.
